(19) United States
(12) Patent Application Publication
(10) Pub. No.: US 2013/0033279 A1
(43) Pub. Date: Feb. 7, 2013

(54) Electromagnetic Test Enclosure

(71) Applicants: James Sozanski, Bolton, MA (US); Fanny Minarsky, Bolton, MA (US); Ron Cook, Groton, MA (US)

(72) Inventors: James Sozanski, Bolton, MA (US); Fanny Minarsky, Bolton, MA (US); Ron Cook, Groton, MA (US)

(21) Appl. No.: 13/195,097

(22) Filed: Aug. 1, 2011

(51) Int. Cl. G01R 31/00

(52) U.S. Cl. 324/750.27

(57) ABSTRACT

The present disclosure is directed to systems and methods for operating, designing, testing and verifying the performance of wireless communication devices. Specifically, the present systems and methods can reliably determine the operating behavior of wireless communication modules within electronic products and devices in a relatively inexpensive and compact testing cabinet, with useful electromagnetically isolating structure, that allows for scalable, multi-application and production line operation and testing and verification of electromagnetic equipment therein.

### TECHNICAL FIELD

The present application relates to testing of electromagnetic components and devices having electromagnetic emitters and/or receivers.

### BACKGROUND

Wireless communication has grown to encompass a huge variety of information transactions between electronic machines. These include cellular communications between hand-held units and base stations, wireless communications between peer devices or master-servant components, and even between components on a same device.

For reliable interoperability, wireless communications have been organized into known formats, generally referred to by the associated protocols, so that multiple parties can communicate effectively using compatible communication devices and methods. This encompasses communications between devices employing same communication protocols but made by different manufacturers in different parts of the world. In some respects, these protocols determine the allowable or preferred techniques for delivering and interpreting data communicated between a plurality of communication devices. In other respects, the protocols determine the way in which information is packaged for transmission over conducting or optical lines or over the air (OTA) in a wireless communication environment.

Furthermore, governmental agencies impose regulations controlling the allowable quality and environmental impact of wireless communications. These regulations may be mandated or required for public sale and use of the devices. Testing of such devices is difficult in small enclosed spaces, especially if the enclosed spaces do not provide far-field spacing between the elements that are in communication with one another or if the walls of the space encroach on the fields created in the small spaces.

Testing of wireless electronics communication products and systems allows for determination of the performance of the communication features of the products and systems. This can permit better design of the wireless components to prevent or minimize the effects of “dead zone” or fade-out or other poor performance problems encountered in many wireless communication products.

Present systems for designing and testing of wireless products lack flexibility, are too costly to make and operate, take up too much space, and generally cannot flexibly permit the testing of the variety and number of devices as described herein.

Other shortcomings of current test systems include that they generally are carried out in a “conducted” test fashion, where the antenna of the device under testing is bypassed. While this improves repeatability, it does not fully capture the real world performance of the device, as the test is conducted without the use of the antenna, which is an important element of the wireless communication system. These systems are not suited for multi-input-multi-output (MIMO) testing of a plurality of wireless modules in a device. Over the air (OTA) testing remains experimental and not suitable for production line use.

Current systems are also not adapted for testing multiple electromagnetic (e.g., radio, RF) communication modalities within a single device. Some present test facilities are poorly isolated from the outside environment. As a result, to compensate for this weakness, many measurements are taken on a device under test and an averaging or statistical result is deduced from the many measurements, therefore taking a longer time to test a single device.

Additionally, current systems do not permit production line testing in any meaningful or efficient way. That is, current testing environments and systems and methods are not scalable for efficient or economical production line testing.

### SUMMARY

As mentioned above, the present inventions related to new and improved systems and methods for operating, designing, testing and verifying the performance of wireless communication devices. Specifically, the present systems and methods can reliably determine the operating behavior of wireless communication modules within electronic products and devices. This includes the ability to reliably and repeatably test the effectiveness of radio frequency (RF), 802.11, cellular, 3G, 4G/LTE, WiMax, Bluetooth, microwave and other electromagnetic receiver, transmitter and transceiver components.

In some aspects, the present systems provide relatively compact enclosures for performing the above design and testing. The enclosures are preferably relatively mobile and small in size compared to typical existing over-the-air (OTA) testing facilities, which are usually room-sized or laboratory-sized and not mobile. The enclosures are also preferably provide isolation from RF, microwave and other electromagnetic interference so that the testing conducted within the enclosures is substantially performed without such interference.

In other aspects, the present enclosure systems are geometrically and operationally adaptable for a variety of applications and uses, as will be explained below. In all, the present testing chambers and the methods for using the same allow for better design of electromagnetic wireless communication systems and components.

In still other aspects, the present systems and methods permit more reliable, repetitive, and production scale testing of said wireless systems. In still other aspects, the present systems and methods permit the testing of multiple input-multiple output (MIMO) wireless features wherein a plurality of different electromagnetic receivers and transmitters are designed to co-exist in a same device.

### IN THE DRAWINGS

FIG. 1 illustrates an exemplary view of a wireless test chamber for testing a plurality of wireless devices;

FIG. 2 illustrates a basic electrical block diagram representative of an illustrative arrangement of a wireless test chamber and devices; and

FIG. 3 illustrates an exemplary method for testing wireless communication devices within a wireless test chamber;

FIG. 4 illustrates an exemplary positioning apparatus used in a wireless test chamber;

FIG. 5 illustrates an exemplary view of a test chamber with a positioning apparatus therein;

FIG. 6 illustrates an exemplary upright frame construction of a multi-chamber electromagnetic test enclosure system; and

FIG. 7 illustrates an exemplary arrangement of a plurality of test enclosures in mechanical and cabled signal communication with one another.

### DETAILED DESCRIPTION

As mentioned above, the present inventions related to new and improved systems and methods for operating, designing, testing and verifying the performance of wireless communication devices. Specifically, the present systems and methods can reliably determine the operating behavior of wireless communication modules within electronic products and devices. This includes the ability to reliably and repeatably test the effectiveness of radio frequency (RF), 802.11, cellular, 3G, 4G/LTE, WiMax, Bluetooth, microwave and other electromagnetic receiver, transmitter and transceiver components.

In some embodiments, the present systems provide relatively compact enclosures for performing the above design and testing. The enclosures are preferably relatively mobile and small in size compared to typical existing over-the-air (OTA) testing facilities, which are usually room-sized or laboratory-sized and not mobile. The enclosures are also preferably provide isolation from RF, microwave and other electromagnetic interference so that the testing conducted within the enclosures is substantially performed without such interference. The enclosures are additionally, in some embodiments, geometrically and operationally adaptable for a variety of applications and uses, as will be explained below. In all, the present testing chambers and the methods for using the same allow for better design of electromagnetic wireless communication systems and components. Also, the present systems and methods permit more reliable, repetitive, and production scale testing of said wireless systems. In still other aspects, the present systems and methods permit the testing of multiple input-multiple output (MIMO) wireless features wherein a plurality of different electromagnetic receivers and transmitters are designed to co-exist in a same device.

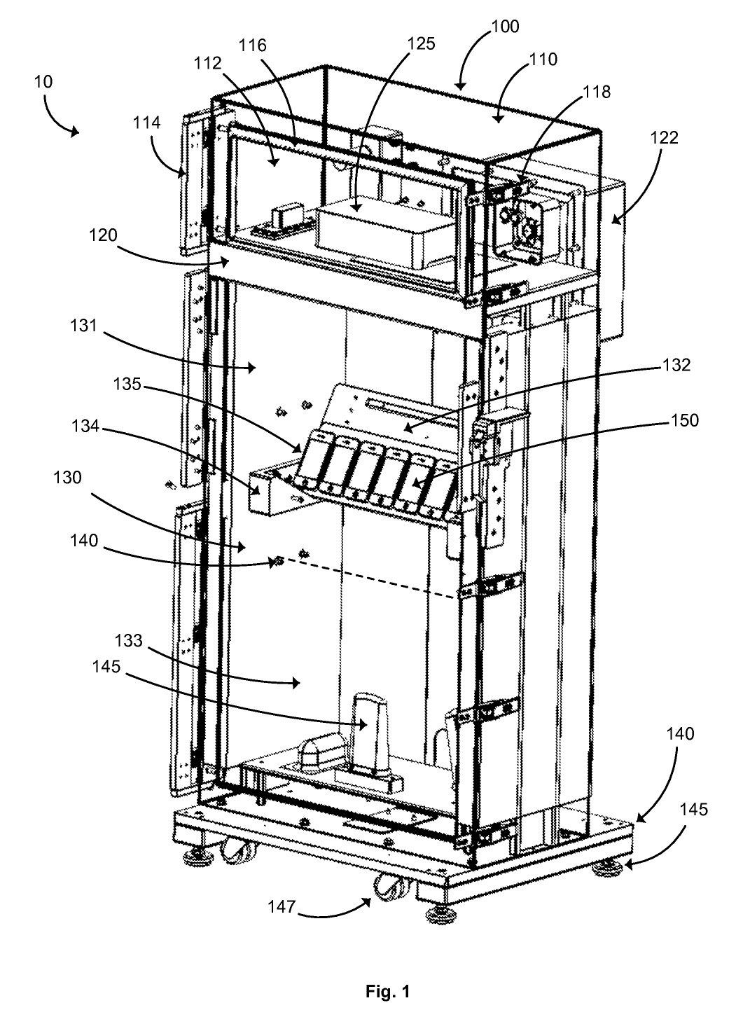

FIG. 1 illustrates a perspective view of an exemplary electromagnetic test enclosure system 10 that can be used for the above purposes to design or test electromagnetic devices (e.g., the performance of transmitting and/or receiving components and antennae). Such a system is herein referred to as a test enclosure though it is to be understood that testing an apparatus or component is but one use of the present system. Other purposes and uses include verification, design, analysis, scientific experimentation, proving or confirming compliance, certification, mass production or production line testing, and others.

Electromagnetic test enclosure system 10 includes a housing 100, which may be formed of one or more individual housing parts. In the embodiment shown, two mechanically coupled enclosures make up the primary enclosure spaces of the system 10. A first (upper) chamber 110 and a second (lower) chamber 130 are coupled to one another and/or separated by an electromagnetically-isolating divider 120. The first (upper) chamber 110 holds a master device 125 such as a base station or radio connected to an electromagnetic antenna 145 disposed in the second (lower) chamber 130 by way of a conducting line, coaxial cable, or other connection as will be described below.

The second (lower) chamber 130 may itself be divided into two or more sub-chambers by use of non-isolating shelves or dividers (represented by dashed line 140) to allow electromagnetic field lines and signals to pass between the two or more sub-chambers of lower chamber 130. For example, a device under testing (or DUT) 150 may be disposed in a first (here upper) part 131 of the second chamber 130 and the master device's antenna 145 may be disposed in a second (here lower) part 133 of the second chamber 130. The DUT 150 and the antenna 145 of the master device 125 can have electromagnetic communication through electromagnetically permissive (RF transparent) divider 140.

As seen in the present embodiment, a plurality of individual DUT devices 150 may be placed in the second chamber 130, and specifically in a first part 131 of the second chamber 130, and still more specifically on a shelf or support member 135 fixed to the walls of the second chamber 130. The plurality of individual DUT devices 150 can include a plurality of identical devices 150 in the context of testing in production environments to increase the throughput of the production line testing.

The test enclosure system 10 includes a housing 100 that is made of walls that substantially isolate the electromagnetic environment on either side of said walls, and are constructed of electromagnetically opaque materials (e.g., metal, alloy, or other conducting solids such as steel in some embodiments). That is, an inside or internal volume is defined and an outside or external volume is defined by said walls. The interior surfaces of the compartments of the test system may be made substantially or partially anechoic so as to absorb or minimize the internal reflection of electromagnetic waves incident upon said internal walls.

In some aspects, one or more of the faces of the enclosure (e.g. a front face) generally has a door that can open and shut for access to the inside of the enclosure. The door or doors are made of electromagnetically opaque material (e.g., steel) are mounted to corresponding hinges 114 that rotate on an axis to permit secure shutting of the doors and electromagnetic isolation of the internal environment volume when the doors are shut.

An operator (human or robot machine) may place the one or more DUT devices 150 onto the support member 135. The door openings 112 may be surrounded by a suitable electromagnetically-tight isolating strip, lip, bevel, chamfer, or gasket that prevents small amounts of radiation from leaking in or out of the areas surrounding the doors when shut. The tightness and isolating capabilities of the doors are further enhanced by the use of secure latches 118 to hold the doors shut when testing is in progress. A warning light may indicate when testing is in progress so that an operator does not accidentally open the enclosure doors and defeat the isolating function thereof.

The doors of the enclosures of the present test system may swing open or shut on hinges as shown in the figure. Alternatively, the doors of the enclosures of the present system may slide on rails, slots, guides or other linear members so that the doors can open and shut securely to expose the interiors of the enclosures when the doors are open and isolate the interior volumes when the doors are shut. The door to a given enclosure may comprise only one panel or it may comprise a plurality (e.g., two) panels that cooperatively move together to open or shut the door to the enclosure. Still alternatively, a door to an enclosure may swing on a pivot upward and outward in a direction parallel to the face of the enclosure wall (fan-like), or in a direction perpendicular to the face of the enclosure wall (gull-wing door style). Accordion style doors, doors that move like those of a conventional garage door and other door styles are also possible for use with the proper materials and mechanical articulation elements as suits a given application.

While the first (master) and second (DUT) compartments or chambers have been illustrated as being one on top of the other, in a given implementation, it may not critically matter if the first and second compartments or chambers are placed above one another, side-by-side, front-to-back, or in another reasonable configuration.

In basic operation, the system 10 allows for wireless electromagnetic communication between a wireless component 145 that can be controlled by a master device 125 and a device under testing (DUT) 150. Various DUT devices 150 may be interchangeably placed in the shielded space in the present enclosure and tested as to the performance of their wireless communication modules and features. This includes testing the multi-modal communication features or MIMO features thereof.

One or more sensor test probes or antennae may be introduced into the test enclosure to make measurements of the electromagnetic field at a location of the one or more test probes or antennae. As will be described below, manual or automated translation and/or rotation or repositioning of any of the DUT or sensor probes or antennae can be used to map out a two- or three-dimensional representation of a characteristic (e.g., strength, intensity) of the electromagnetic field within the enclosure.

Optionally, the whole assembly system may be mounted on stationary mounts or legs. Alternatively, as shown, a support platform 140 may be moveable so that the system 10 can be moved from one place to another on rollers 147 and support legs 145. The rollers 147 may comprise bearings, wheels, casters and the like to permit sliding and translational movement of the system 10 over a solid floor. The support legs may be engaged into the platform 140 by threaded extensions mated to threaded portions of platform 140 to permit leveling and securing of the placement on uneven floors by proper extension of the threaded extensions.

In some embodiments, the second (DUT) compartment or chamber 130 is longer in one dimension than in the others. For example, in an upright format as shown in the present example, the second (DUT) compartment 130 may be taller than it is wide or deep. In this way, the overall dimensions of the system 10 can be kept relatively small and compact, but a long dimension can be maintained that allows for far-field communication between the DUT and the master antenna in said second chamber 130. In such a system a positioning apparatus or positioning rack may be included to allow relative movement and positioning of the DUT with respect to the master antenna. In this way, while only one dimension of the compartment 130 is sufficiently long to provide the needed far-field measurements, the DUT and its antenna can be oriented at will so as to take measurements in the long direction of the enclosure. Therefore, a test enclosure does not need to be constructed with far-field dimensions in each of its dimensions (height, width, depth). Those skilled in the art will appreciate the advantage of making measurements in a test environment permitting far-field spacing between the equipment therein. The far-field dimension may be determined by the aperture (size) of the antennae, the operating frequency (or wavelength), and other known parameters. Therefore, a test enclosure can be sized and designed to suit testing of a variety of compact communication systems in known RF or other wavelength ranges.

In some aspects, the present test system is one of a plurality of such test systems in a production line testing station. It can be seen that, especially given its compact nature, the present test enclosure can be placed side by side along with a number of such enclosures so that an operator can conduct testing on a first test system while another operator conducts testing on a second test system and so on to increase the throughput of the testing facility or station.

It can be seen that the master device 125 may locally itself generate the test signals sent to the master antenna 145. However, by proper shielded connection to the outside environment, the master device 125 may receive external signals for delivery to the master antenna 145.

Still other aspects allow for the master device 125 or another source of test signals to be located remotely from the testing station 10. For example, the source of the test signals being sent to master antenna 145 can be a computer or amplifier or master device that is placed off-site or in another room, or the test signals can come from the computer of an engineer or test operator sitting half way around the world, said signals delivered over a network connection. The same can be said for the measurements collected by the test system, which can be delivered to the master device 125 or to any other device coupled thereto by a communication cable, fiber, or network.

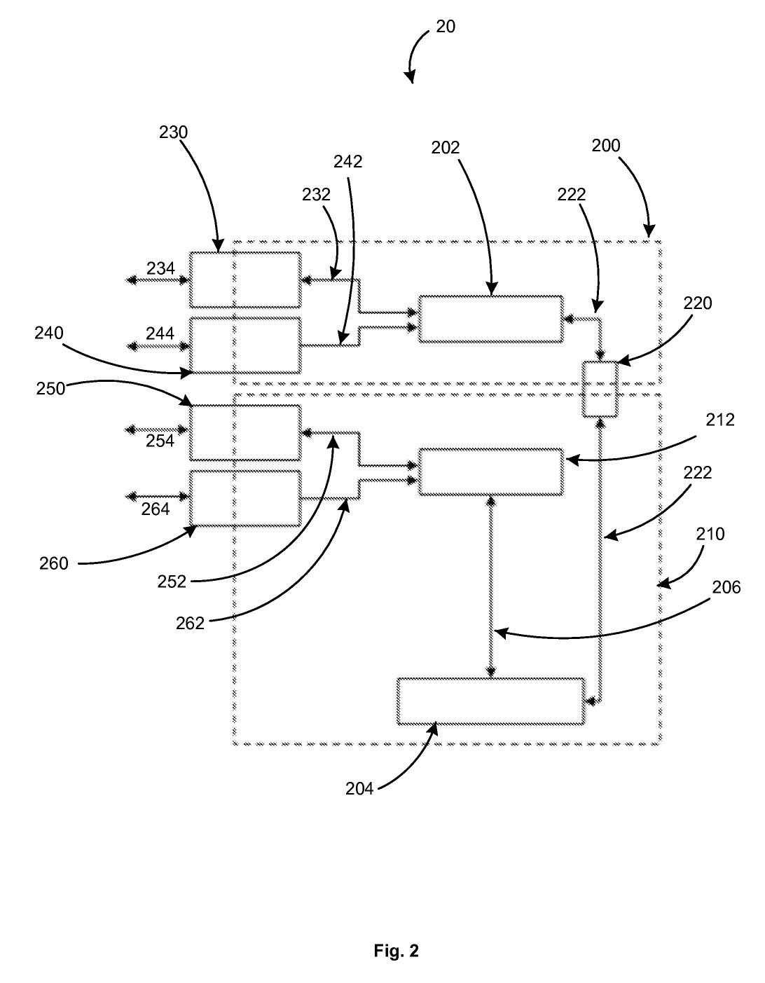

FIG. 2 illustrates a simplified electrical block diagram 20 showing some primary components and connections as would present to an operator testing a DUT in the present enclosure systems. Some components of the system are disposed within a first (master device) chamber 200, while other components are disposed within a second (DUT) chamber 210. As stated before, the master and DUT chambers are preferably constructed of an electromagnetically shielding or opaque material such as steel. In some embodiments a steel box forms the basis of the frame for each of the chambers.

A master device 202 is located within master chamber 200. The master device 202 is used to generate test signals to be delivered to the DUT 212 by a test antenna 204. Both the DUT 212 and master test antenna 204 are located in the DUT chamber 210. The master test antenna 204 also receives wireless signals from DUT 212 so that the master device 202 can record and operate on such signals received from the DUT 212.

The equipment in the master and DUT chambers 200 and 210 are substantially isolated from electromagnetic radiation between the chambers, and the interior of the chambers are furthermore electromagnetically isolated from the environment outside the chambers. For this reason, cables or conducting lines such as coaxial conductor cables are used to carry signals in to and out of the shielded chambers 200, 210 when required. According to some embodiments, either one or both of the master and/ or DUT chambers may have connection, interface, or coupling capabilities to the exterior of the enclosure through appropriately shielded and/or filtered connection points. So for example, the master device 202 may be coupled to an external device or network or computer storage apparatus by way of a shielded and filtered coaxial line or fiber optic or other communication pathway which passes through a connection panel on the back of the master chamber 200 through which the communication pathway may pass. Specifically, in one embodiment, a coupling panel may be installed in a wall of the chamber. The coupling panel may have a first face proximal to or facing inward towards the interior of the chamber and a second face proximal to or facing outwards towards the exterior of the chamber. Suitable connection points, plugs, jacks, or terminator connectors are built into the inner and the outer faces of the coupling panel. Separate conducting or fiber lines or cables can be then connected to respective terminator connectors on the respective first and second faces of the coupling panel to establish communication between the inside and the outside of the chamber without directly passing a wire or line through the walls of the chamber.

To best isolate the components within chambers 200, 210 yet allow hard wired signaling therebetween, RF conducting cables 222 are employed to carry signals between the master device 202 and its master test antenna 204. Furthermore, to avoid leakage of unwanted or extraneous signals into the shielded test environs, the couplings are adequately shielded and filtered. A master input/output (I/O) filter 230 and a master power filter 240 are coupled to the master device 202 by I/O and power conducting lines 232 and 242 respectively. A DUT I/O filter 250 and DUT power filter 260 are likewise coupled to the DUT 212 by I/O and power lines 252 and 262 respectively. The I/O and power filters 230, 240, 250, 260 are coupled to automation equipment that allows automating the present processes.

The DUT chamber 210 may be electromagnetically considered as a single enclosed volume but it may in practice be divided into a plurality of separate volumes as was described in the earlier figure. Mechanically, the DUT chamber may be divided into two or more volumes by RF-permissive or transparent dividers, walls, shelves and so on. In a preferred embodiment, the DUT 212 and the master antenna 204 are in RF communication within the DUT chamber 210, but a plastic divider separates the physical volume of the DUT chamber 210 into two separate volumes, one housing the DUT device 212 and the other housing the master antenna 204. Separate doors or access panels may be provided to the DUT side of the chamber 210 and the master antenna side of the chamber 210. In this way, an operator during production can open the door to the DUT portion of the chamber to swap out or maintain or operate on the DUT without disturbing the master antenna.

RF feed-through connector 220 is used to electrically couple the RF conducting cables 222. All openings, seams, joints, and other apertures where electromagnetic radiation may leak is electrically and/or mechanically secured and plugged or shielded to reduce unwanted interference and minimize errors in electromagnetic field measurements within the test enclosure.

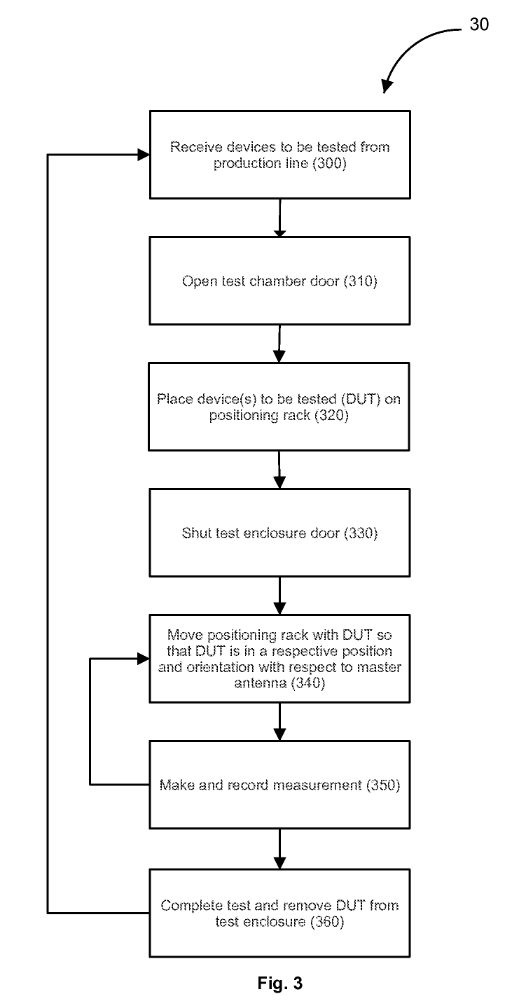

FIG. 3 is provided to illustrate how the present systems and methods enable useful and new processes and design and verification results. A method 30 for production line testing of wireless devices (DUTs) is described. Other ancillary steps and optional processing acts are also envisioned and would be apparent to one of ordinary skill in the art upon reviewing the present disclosure.

A human or robotic operator may be situated in the production environment. The production environment can be an assembly line or one or more testing stations. Products having wireless electromagnetic communication capabilities are designed, manufactured and prepared for testing. The products to be tested (devices under test, DUTs) are received at step 300 at the human or robotic testing station that includes the present electromagnetically-isolating test enclosure systems as illustrated earlier. At step 310, the operator opens an appropriate aperture or door so that he or she or it can access the equipment inside a compartment of the test enclosure system. In production line testing, the operator places one or more DUTs to be tested on a positioning rack at step 320.

The door to the test enclosure is shut securely at step 330 after the DUTs are positioned therein on the positioning rack. The positioning rack is moved at step 340 as desired throughout testing and a measurement is made and recorded at step 350. The results of the measurement may be stored in a data file on a digital storage medium or computer memory device. Also, the results of a certain measurement may be transmitted in real time to a quality control officer or to a computer program monitoring the results of the testing. The data from test measurements can be transmitted serially or collected and transmitted in batch format. Optionally, a serial number of a DUT under investigation, a date and time of test, or other environmental settings and parameters may be included in a data file including test data for the DUT.

When describing the positioning of the DUT it should be appreciated that this step may include manual positioning of the positioning system or rack by an operator to achieve particular positions in which measurements are to be taken, or alternatively, automated positioning using computer control to achieve the same goal. In one example, measurements are taken uniformly as the DUT is translated, with a measurement made at successive distances from the master antenna. In another example, the DUT's distance from the master antenna is set, then the DUT is rotated about an axis. For example, the DUT may be rotated azimuthally or in a plane including a long axis of the master antenna. Electromagnetic field strength measurements may be taken at regular or non-regular intervals. For example, more frequent measurements may be made if the variation of field strength is changing rapidly and less frequent measurements may be made when the field strength is changing relatively slowly.

As mentioned, the DUT may be re-positioned after a measurement is taken, and the positioning and measurement sequence (steps 340 and 350) can be repeated until sufficient data is collected regarding the electromagnetic performance and characteristics of the DUT.

Testing of a plurality of input and output modalities is possible using the present system and method, including testing of devices having multiple-input-multiple-output (MIMO) capabilities. Examples are modern smart phones that include cellular (and in some cases multiple types of cellular support), WiFi (802.11), Bluetooth™, global positioning system (GPS) and other radios that operate substantially at the same time and support different corresponding applications.

At step 360, when the needed test measurements are completed, the testing is terminated and the DUT or DUTs may be removed and sent along to the next step in the production process. If the DUTs pass the required tests, this may be indicated by a certification stamp and the DUTs may be cleared for shipment to customers or final production steps. If the DUTs fail the tests other actions may be taken. For example, the failing DUTs may be discarded, returned to the manufacturing station for repair of the wireless components, replacement of one or more components, retesting, or other measures. In some cases, the products being tested may be placed into “first class” and “second class” categories based on the performance of the products, with the better performing products receiving a “first class” rating or some other designation, and possibly selling for greater price or even receiving different model number, lot number, or other markings.

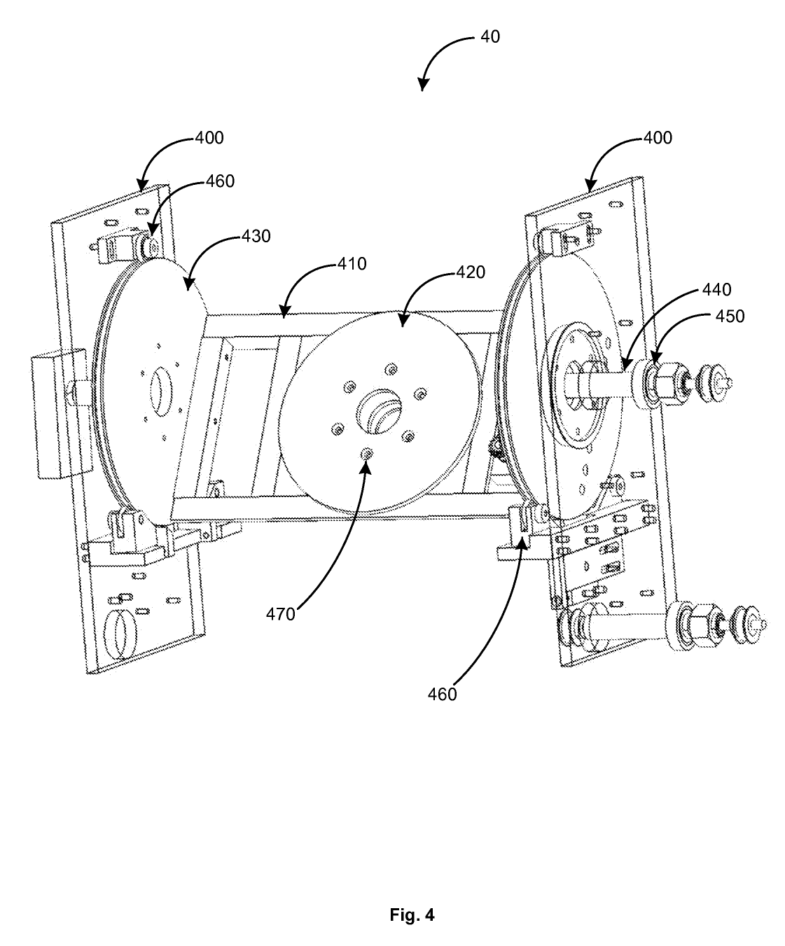

FIG. 4 illustrates an exemplary positioning apparatus 40 used with or as part of the present test systems. The positioning apparatus 40 includes one or more structural members 400 that form a frame of the apparatus and allow other components to be fixed thereto and allow the positioning apparatus to interface with the overall device testing system. Support platform 410 may be a rack, shelf, or other member as discussed and shown herein to support or hold the DUT or plurality of DUTs being tested. Securement of the DUT may be provided by a suitable mount, bracket, clip, or mechanical feature. A platter 420 having one or more screw mounts or retaining elements 470 is used in the illustrated embodiment to aid in the securing and positioning of the DUT. Rotating members, for example gears or frictional wheels 430 are moved by way of a motor and are supported on rollers 460 to permit rotational movement of bracket or shelf member 410 and platter 420. The rotation is accomplished by a motor (not shown) that is placed outside the test enclosure but is coupled by an axis or shaft 440 and bearing 450. Feedback or position detection may be provided by sensors that sense the angular or translational orientation and position of the DUT or other component of the positioning apparatus 40. The position is then relayed to the position controller in real time. In some embodiments, the side support members 400 are substantially fixed to the walls of the test chamber, e.g., the lower DUT chamber mentioned previously.

One or more position controllers may be employed to control the position of a device under test (DUT) within the RF shielded enclosures and relative to other things such as the master antenna described above. In a preferred embodiment or embodiments, the positioning of the DUT is performed in an automated way using computer controls.

One advantage of automated positioning is that many positions and corresponding measurements may be made, which is tedious for a human operator to accomplish with accuracy in a short time. Another advantage of automated positioning and testing is that a computer running a test program or algorithm may automatically seek certain informative and useful positions in which to place the DUTs and make corresponding measurements. Optimization techniques and non-uniform gridding may be applied to seek positions and test cases to collect data in an automated fashion so as to determine the performance of the DUTs. Steepest descent, least steep descent and other gradient methods can also be employed to quickly and efficiently conduct the testing so that a greater throughput of products can be tested and verified in a production line environment. When the antenna patterns of the DUT products are not geometrically uniform, the present techniques are especially useful so as to map out the field sensitivity or radiative power profile of the DUT wireless communication modules and antennae.

The positioning rack may be generic to hold the one or more DUTs, but may also be customized to suit the size, shape, weight, or other dimensions of the DUTs. Electrical couplings and connections may be provided integral with the positioning rack to mate with or supply signals and power to or from the DUTs placed into the positioning rack. For example, if the DUTs include portable hand-held communication devices (e.g., cellular phones, games, PDAs, etc.) an NC or D/C power connection may be provided to power the DUTs during testing. Other data connections and interfaces and plugs can also be provided for convenience, and may be constructed integrally with the positioning rack design.

The DUTs may be supported on the positioning rack and rest thereon by their own weight under the force of gravity, or the DUTs may be fixed to the positioning rack by way of straps, hook-and-loop tape, adhesive strips, clips, snaps, or other mechanical fixative members so that the DUTs do not slip off of or accidentally shift in their place during testing. This especially since the positioning rack may be moveable and is generally able to translate and/or rotate within the test enclosure during testing. The DUTs may also be placed into form-fitting foam or sponge or polymer forms that substantially grasp the DUTs firmly so that they are both safe from damage and controllably moveable during testing as needed.

In some testing procedures, the positioning rack system is used to translate, rotate and generally position the DUTs in three dimensions upon manual or computer-controlled instruction from a positioning control system that controls the position of the positioning rack. The positioning rack may be moved by motors, lead screws, synchros, or other prime movers in any reasonable coordinate system. In some embodiments, a X-Y-Z positioning system is used for translation of the DUTs using the positioning rack by way of computer controlled motors in each of the X, Y, Z Cartesian coordinate directions relative to an origin in the laboratory coordinate frame. Cylindrical or spherical or other coordinate systems can be used to determine the location of a DUT and control its position and movement as well.

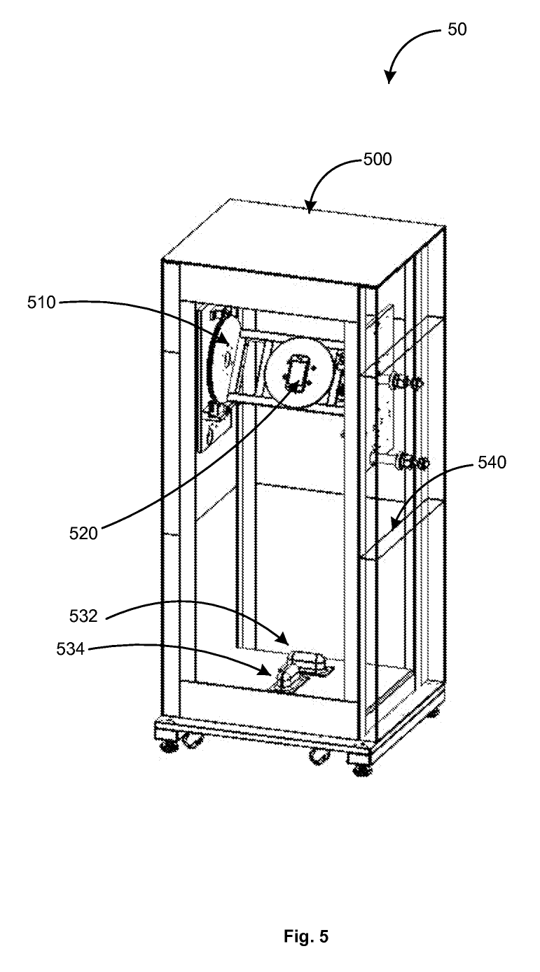

FIG. 5 illustrates an exemplary combined test enclosure and DUT positioning system 50. The system includes a RF-resistant or shielding housing 500, e.g. a grounded metal housing. One or more compartments of the enclosure system are provided with master antennae to communication with the DUT. Here, two such antennae 532, 534 are shown in a relative fixed orientation with respect to one another and housing 500. However, in other embodiments, the antennae 532, 534 may be moveable themselves using positioner devices. The DUT 520 is disposed on and fixed to a DUT positioning apparatus 510 in the same RF compartment as master antennae 532, 534. But the DUT 520 and DUT positioning apparatus 510 may be separated from the master antennae by a RF-permissive or transparent (e.g., plastic or wooden) shelf at location 540 for convenience of operation. External driving and control of the positioning apparatus 510 are allowed.

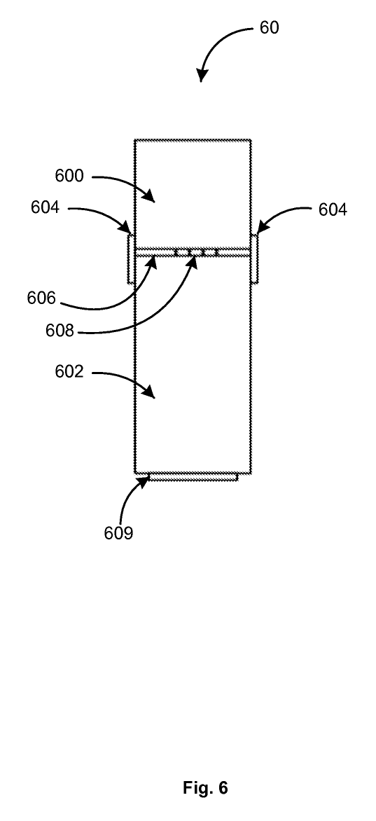

FIG. 6 illustrates an exemplary mechanical arrangement for construction of an electromagnetic test enclosure 60. An first (upper) chamber 600 and a second (lower) chamber 602 are provided for housing the master device, DUT and master antenna. As described before, the master device may reside in the first chamber 600 while the DUT and master antenna reside in respective portions of second chamber 602. The entire assembly 60 can sit on a stationary platform, legs, or on rolling casters or wheels as shown before, 609.

The first and second chambers are mechanically secured to one another by support members 604. The support members 604 may be, like the shells of chambers 600 and 602, made of a metal such as steel. Support members 604 can be secured to each of the first and second chambers by bolts, screws, pop rivets, welds, brazing, or other secure and suitable attachment hardware.

The interface 606 between first and second chambers 600, 602 provides for one or more communication lines, cables, or wires 608 (e.g., coaxial cables) to carry signals between the first and second chambers 600, 602. Such signals may include the antenna driving signal or test signals or measurement signals. A solid backing plate may be located behind the cables to protect them from mechanical damage and to further shield them from RF fields. Alternatively, a solid channel (for example a hollow rectangular-cross-sectioned channel) may be employed to run the cables through it to achieve the present goals.

It can be seen from the present example that some designs for the test enclosure are generally upright and have a relatively tall frame with a relatively compact base or footprint. In this way, it may be convenient for a standing or seated operator to access the equipment within the enclosure chambers during operation. Also, the enclosure system 60 will require less square footage on the floor of a shop or manufacturing facility. In this way, several upright test enclosure systems may be set up near each other at a testing station employing several operators testing numerous DUT machines at the same time. Additionally, by designing the enclosure system with an elongated dimension (e.g., height) there is ample room in the elongated dimension for achieving far-field wireless communication between the DUT and the master antenna in the DUT chamber of the system.

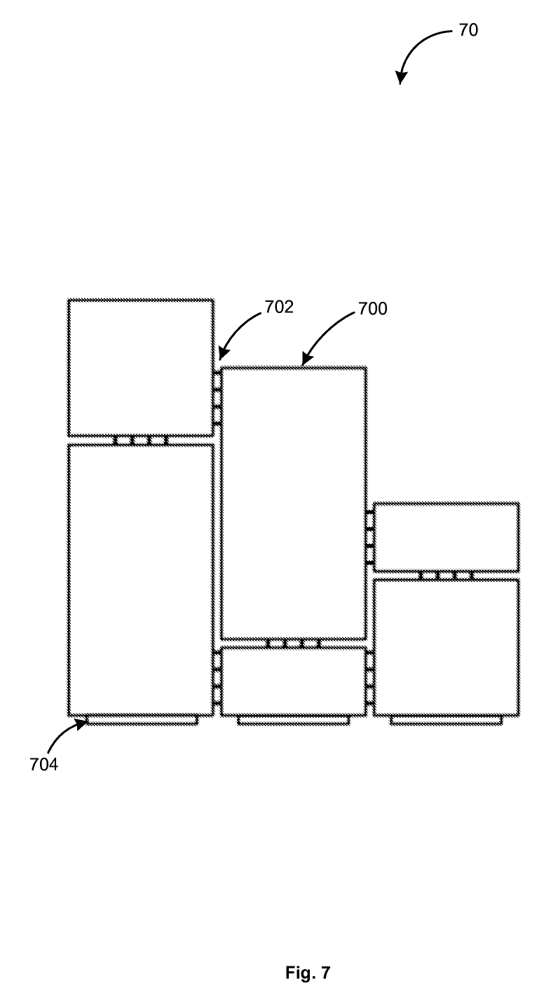

FIG. 7 illustrates an exemplary arrangement of a test station 70 comprising a plurality of electromagnetic test chambers 700. The individual test chambers 700 may be meshable or connected electrically through signal pathways in a mesh network arrangement. Signal pathways 702 like those described above allow selectable passage of communication or driving or test signals between the various test chambers 700. Each one or group of enclosure chambers may rest on stationary or moveable base supports 704 where they contact the laboratory floor. A complex system of wireless communication devices may be placed in the various chambers 700 and tested in controlled environments as needed for a given scenario. For example, a multi-radio transmitter/receiver scenario can be tested. Test sensors can be placed in one or more of the modules as needed.

It can be appreciated that an arbitrary number of test chambers can be coupled as described and shown. A plurality of side-by-side or stackable modular test chamber modules can be employed. Electrical quick disconnect connection lines (e.g., BNC or coaxial or serial or parallel connections) can be used to electrically make the meshed modules in signal communication with one another while remaining substantially electromagnetically isolating as to their interior volumes. Mechanical supports and interlocking hardware can be used to fix the modules to one another in the arbitrary desired configurations.

In one or more embodiments, the present test enclosure system may be constructed to be expandable (or collapsible) in at least one dimension. Specifically, the system may include a compartment or chamber that has telescoping walls in one dimension. The system may be collapsible for compactness but may expand telescopically by slidably moving a plurality of wall sections along a direction parallel to their expanse so that the height (or width or depth) can be expanded form a first shorter size to a second longer size. Alternatively, the system may be provided (e.g., sold) with replaceable wall sections so that the user can install a first shorter wall size if desired, but if testing larger components or longer wavelengths the user can substitute the first shorter wall section with a second longer wall section to make the testing enclosure larger in the dimension of said walls. In still other embodiments, the system may be provided in modular units that allow its user to install a desired number of modular units that stack or securely interlock with one another so that a desired dimension can be achieved.

It should be noted that in some aspects, the positioning system and its mechanical components are constructed of RF-compatible or electromagnetically-permeable materials such as plastic, wood, some ceramics, and some types of glass or fiber boards (natural or synthetic). This minimizes the effect of the positioning system on the measurements being made during testing and allows for a more natural simulation of the performance of the devices under test (DUTs).

The present invention should not be considered limited to the particular embodiments described above, but rather should be understood to cover all aspects of the invention as fairly set out in the attached claims. Various modifications, equivalent processes, as well as numerous structures to which the present invention may be applicable, will be readily apparent to those skilled in the art to which the present invention is directed upon review of the present disclosure. The claims are intended to cover such modifications and equivalents.

What is claimed is:

1. A system for testing electromagnetic components, comprising:
a first electromagnetically-isolated chamber for housing a first wireless communication component;
a second electromagnetically-isolated chamber for housing a second wireless communication component and an antenna of said first wireless communication component;
said first and second chambers comprising electromagnetically-isolating walls that substantially define respective first and second interior volumes of their respective chambers;
said first and second chambers each further comprising an access port that allows access to said respective interior volumes thereof when open and substantially isolates said respective interior volumes from external electromagnetic fields when shut;
said first and second chambers being in mechanical and in signal line communication with one another so that signals can pass between said first and second chambers by way of at least one signal line, including a signal line coupling said first wireless communication component and the antenna of said first wireless communication component.

2. The system of claim 1, said walls comprising anechoic surfaces facing inwardly into said interior volumes.

3. The system of claim 1, comprising an electromagnetically-isolating divider separating said first and second chambers.

4. The system of claim 1, said electromagnetically-isolating walls comprising steel walls.

5. The system of claim 1, said access ports comprising perimeter edges thereof having electromagnetically-isolating gasket material thereon to better seal said access ports when they are shut.

6. The system of claim 1, said first wireless communication device comprising a master communication device and said second wireless communication device comprising a device under testing.

7. The system of claim 1, said second chamber comprising a positioning apparatus for securing and positioning a device under testing.

8. The system of claim 7, said positioning apparatus providing motion in at least two degrees of freedom.

9. The system of claim 7, said positioning apparatus providing motion in at least one translational and at least one rotational degree of freedom.

10. The system of claim 7, permitting substantially simultaneous testing of a plurality of devices under testing.

11. The system of claim 10, said positioning apparatus designed and constructed for simultaneously supporting said plurality of devices under testing.

12. The system of claim 7, said positioning apparatus including integrated electrical connectors for coupling to said device under testing.

13. The system of claim 7, said positioning apparatus being controllable by a microprocessor based positioning controller.

14. The system of claim 1, said second chamber comprising an elongated dimension sufficient to allow substantially far-field wireless communication between said second wireless communication component and said antenna of said first wireless communication component.

15. The system of claim 1, further comprising brackets for mechanically coupling one or more chambers to one or more other chambers in a modular fashion.

16. The system of claim 1, further comprising a solid conduit through which said signal lines pass between said first and second chambers.

17. The system of claim 1, said first and second chambers being constructed of substantially independent enclosures in mechanically and signal communication with one another while being substantially isolating said interior volumes from one another.

18. The system of claim 1, said first and second chambers being formed by separating a monolithic electromagnetically-isolating box into said first and second chambers using an electromagnetically-isolating separator defining said first and second chambers.

19. The system of claim 1, further comprising one or more electromagnetically-permissive mechanical dividers that divide a single electromagnetic chamber into a corresponding plurality of mechanical portions.

20. The system of claim 1, further comprising a sensor antenna for making an electromagnetic field measurement at a given spatial location.

21. The system of claim 1, comprising a plurality of connectors and sensors for testing a plurality of different wireless communication components within a single device under testing.

22. The system of claim 1, further being integrated into a testing station in a production line that processes multiple devices under testing.

23. A method for testing wireless communication devices, comprising:
a) receiving a wireless communication device for testing from a production assembly line;
b) opening an access port in a testing chamber;
c) placing said wireless communication device into said testing chamber through said access port;
d) closing said access port to electromagnetically seal an interior volume of said testing chamber;
e) positioning said wireless communication device to a desired location and orientation with respect to a master antenna in said chamber;
f) providing a master test signal from a master test device to said master antenna;
g) receiving a response signal from said wireless communication device;
h) recording said response signal;
i) repeating steps (e)-(h) at least one more time; and
j) determining a performance metric of said wireless communication device based on said received response signals.

24. The method of claim 23, further comprising placing a plurality of similar wireless communication devices into said testing chamber and testing said plurality of devices substantially at the same time while enclosed in said chamber together.

25. The method of claim 23, further comprising automatically determining a desired position in which to place the wireless communication device, providing signals from a controller to a positioning apparatus to set the wireless communication device in said desired position, taking an electromagnetic field measurement with the wireless communication device in said desired position, repositioning said wireless communication device, and repeating said measurement until said performance metric is determined.

26. The method of claim 25, further comprising using a gradient method in determining said desired position.

27. The method of claim 26, further comprising testing a plurality of different wireless communication modalities in a single wireless communication device substantially at a same time.
